(19) United States
(12) Patent Application Publication
(10) Pub. No.: US 2026/0031779 A1
(43) Pub. Date: Jan. 29, 2026

(54) SQUELCH CIRCUIT

(71) Applicant: MACOM Technology Solutions Holdings, Inc., Lowell, MA (US)

(72) Inventor: Ariel L. Vera Villarroel, Lake Oswego, OR (US)

(21) Appl. No.: 18/780,897

(22) Filed: Jul. 23, 2024

(51) Int. Cl. H03F 3/45

(52) U.S. Cl. CPC H03F 3/45475

(57) ABSTRACT

Amplifiers incorporating squelch circuits and functionality are described. An example amplifier circuit includes an amplifier and a squelch circuit coupled to the amplifier. The squelch circuit is configured to squelch an output of the amplifier by bypassing current from the amplifier. The squelch circuit can include a bypass switch coupled with a transistor of the amplifier and a control circuit coupled to the bypass switch. The control circuit can be configured to control operation of the bypass switch. The bypass switch can be implemented as a bypass transistor coupled in parallel with a transistor of the amplifier. The control circuit can include a biased voltage divider leg with a pair of resistors, a current source coupled at a node between the pair of resistors, and a pair of control switch transistors coupled across a resistor among the pair of resistors.

### BACKGROUND

A range of different amplifiers are known and relied upon for data communications. Differential amplifiers, as an example, are commonly used for high-speed data communications. Differential amplifiers are designed to amplify the difference between two input signals and to reject noise or interference that is present on both (i.e., common to) the input signals. Differential amplifiers are often used as the first amplifier stage in operational amplifiers, and multiple stages of differential amplifiers can be cascaded depending on design needs and the amplification application.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

Amplifiers incorporating squelch circuits and functionality are described. An example amplifier circuit includes an amplifier and a squelch circuit coupled to the amplifier. The squelch circuit is configured to squelch an output of the amplifier by bypassing current from the amplifier.

The squelch circuit can include a bypass switch coupled with a transistor of the amplifier and a control circuit coupled to the bypass switch. The bypass switch can be implemented as a bypass transistor coupled in parallel with a transistor of the amplifier. The control circuit can include a biased voltage divider leg with a pair of resistors, a current source coupled at a node between the pair of resistors, and a pair of control switch transistors coupled across a resistor among the pair of resistors.

In other aspects, the amplifier can include a pair of common collector transistors. The bypass switch can include a first bypass switch coupled in parallel with a first transistor among the pair of common collector transistors, and a second bypass switch coupled in parallel with a second transistor among the pair of common collector transistors. The control circuit can be configured to control operation of the first and second bypass switches. For example, to squelch the amplifier, the control circuit can be configured to provide, to the first and second bypass switches, a control signal having a potential greater than a common DC bias at inputs of the pair of common collector transistors.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an example multi-stage amplifier according to various examples described herein.

FIG. 2 illustrates an example amplifier circuit with squelch circuit according to various examples described herein.

FIG. 3 illustrates another example amplifier circuit with squelch circuit according to various examples described herein.

### DETAILED DESCRIPTION

Receivers, transmitters, and transceivers for emerging data communication applications rely upon amplifier circuits to transfer data signals at higher speeds. The amplifier circuits are often designed for broadband operation and minimal power consumption, but a range of different operating criteria can be important for an amplifier depending on the application. Multiple stages of differential amplifiers can be cascaded or connected in series depending on the design needs of a given amplifier application.

Squelch is a function of some amplifiers for system testing, trimming, and other purposes. The gain of an amplifier is reduced significantly during squelch operations. The output of an amplifier should become relatively negligible during squelch operations but the biasing should not change, for example, so that the remaining components in the amplification chain can be evaluated and optimized.

Reduction of the amplifier gain can be implemented in a number of different ways, such as by powering down an amplifier or parts of an amplifier. Powering down an amplifier during low gain operations can have undesirable effects, however, as it alters the total power consumption of the overall amplification chain or system, which can produce unexpected and unrepresentative voltage fluctuations on operating rails, among other issues. Powering down only certain parts of amplifiers can also subject other circuit components to stresses that can degrade or damage components in sensitive amplifiers. The embodiments described herein include squelch circuit concepts capable of reducing gain by an order of 100-fold or more while also avoiding the stress attributed to powering down amplifier components.

An example amplifier circuit includes an amplifier and a squelch circuit coupled to the amplifier. The squelch circuit is configured to squelch an output of the amplifier by bypassing current from the amplifier. The squelch circuit can include a bypass switch coupled with a transistor of the amplifier and a control circuit coupled to the bypass switch. The control circuit can be configured to control operation of the bypass switch. The bypass switch can be implemented as a bypass transistor coupled in parallel with a transistor of the amplifier in one example. The control circuit can include a biased voltage divider leg with a pair of resistors, a current source coupled at a node between the pair of resistors, and a pair of control switch transistors coupled across a resistor among the pair of resistors.

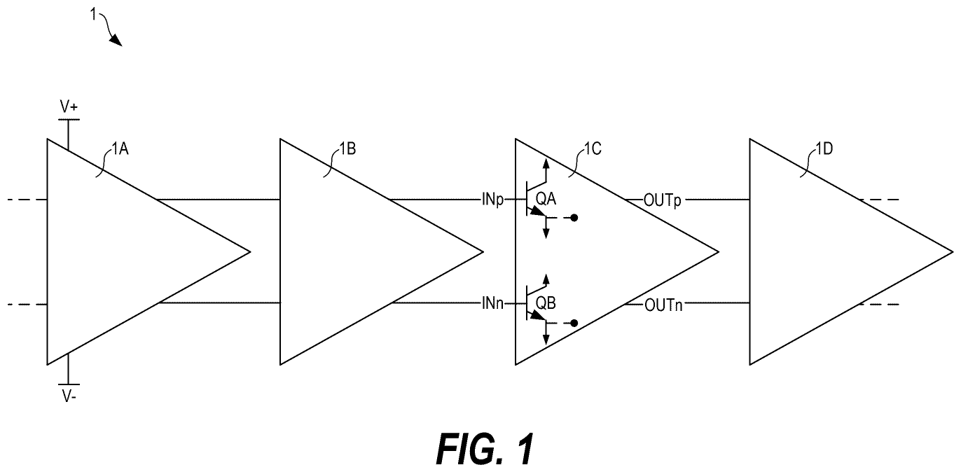

FIG. 1 illustrates an example multi-stage amplifier 1 according to various examples described herein. The multi-stage amplifier 1 can be embodied in various ways, such as using discrete components, as an integrated circuit device formed on a substrate, or as a combination of discrete components and integrated devices. The multi-stage amplifier 1 is depicted as a representative example. The multi-stage amplifier 1 is not exhaustively illustrated in FIG. 1, and the multi-stage amplifier 1 can include additional components that are not shown.

The multi-stage amplifier 1 includes a number of cascaded amplifier circuits or stages, including amplifier stages 1A-1D, among possibly others. In the cascaded configuration shown, the outputs of the amplifier stage 1A are provided as inputs to the amplifier stage 1B. The outputs of the amplifier stage 1B are provided as inputs to the amplifier stage 1C, and so on. Multi-stage amplifiers can be relied upon for increased overall gain over a broad, to tailor input or output impedances, or to achieve other objectives. Each of the amplifier stages 1A-1D is supplied with power by an upper rail voltage or potential V+ and a lower rail voltage or potential V−.

Each of the amplifier stages 1A-1D can include one or more transistor amplifiers, biasing circuitry, coupling circuitry, and related circuit components. Additionally, the transistor or transistors in each of the amplifier stages 1A-1D can be arranged or configured in different ways (e.g., differential pair, Darlington pair, common collector or drain, common emitter or source, or common base or gate, etc.) depending on the design, objectives, and application for the multi-stage amplifier 1. The amplifier stage 1C is shown to include two common collector transistors QA and QB, as an example, for handling a differential signal.

Each of the amplifier stages 1A-1D can be designed, tailored, and optimized independently. It can be helpful in some cases for one or more of the amplifier stages 1A-1D to include a squelch function for trimming, testing, and other purposes. The amplifier stage 1C, for example, can include a squelch function according to aspects of the embodiments. The signal output power level of the amplifier stage 1C can drop very significantly and become relatively negligible during squelch operations. The squelch function in the amplifier stage 1C can be helpful for trimming, testing, or evaluating other amplifier stages or components in the multi-stage amplifier 1. However, the squelch concepts described herein are not limited to use with multi-stage amplifiers, amplifiers at any particular location in a multi-stage amplifier, or any particular type of amplifier. The squelch concepts can be extended to and used with a range of different types of amplifiers.

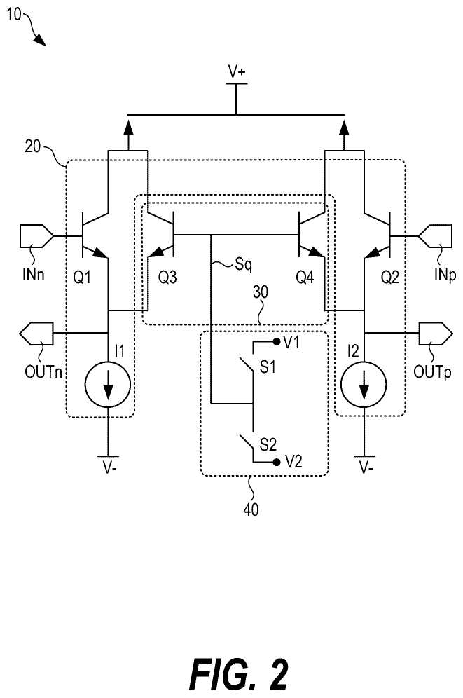

FIG. 2 illustrates an example amplifier circuit 10 with squelch circuit according to various examples described herein. The amplifier circuit 10 can be embodied in various ways, such as using discrete components, as an integrated circuit device formed on a substrate, or as a combination of discrete components and integrated devices. The amplifier circuit 10 is provided as a representative example of an amplifier stage with a squelch circuit and squelch functionality. The amplifier circuit 10 is not exhaustively illustrated in FIG. 2, and the amplifier circuit 10 can include additional components that are not shown. The amplifier circuit 10A can also omit certain components in some cases.

The amplifier circuit 10 includes an amplifier or amplifier stage 20 (also “amplifier 20”) and a squelch circuit coupled to the amplifier 20. The squelch circuit includes a bypass switch 30 and a control circuit 40. The amplifier 20 can be used as an amplifier stage for radio frequency (RF) communications, wired communications, optical communications, or for other purposes, without limitation. The amplifier 20 can also be an amplifier stage in a multi-stage amplifier, such as the multi-stage amplifier 1 in FIG. 1. The bypass switch 30 of the squelch circuit is coupled to the amplifier 20 and also receives a squelch control signal “Sq” from the control circuit 40, as described in further detail below.

The amplifier 20 includes two transistors Q1 and Q2 and two current sources I1 and I2. The transistors Q1 and Q2 are depicted as bipolar junction transistors in FIG. 1. However, the transistors Q1 and Q2 can be embodied as field effect transistors (FETs), and the concepts described herein are not limited to use with amplifiers or transistors of any particular type or technology. The transistors Q1 and Q2 are configured as a pair of common collector transistors in the example shown in FIG. 2, although other types and configurations of amplifiers and amplifier circuits can also incorporate the squelch circuit and functionality concepts described herein.

The collectors of the transistors Q1 and Q2 are coupled to the upper rail voltage or potential V+. An output OUTp (e.g., positive or non-inverting output) of the amplifier 20 can be taken from the emitter of the transistor Q1. The base of the transistor Q1 operates as an input INp (e.g., positive or non-inverting input) of the amplifier 20. The emitter of the transistor Q1 is coupled to the current source I1. The current source I1 is coupled between the emitter of the transistor Q1 and the lower rail voltage or potential V−, which can be ground potential in some cases.

An output OUTn (e.g., negative or inverting output) of the amplifier 20 can be taken from the emitter of the transistor Q2. The base of the transistor Q2 operates as another input INn (e.g., negative or inverting input) of the amplifier 20. The emitter of the transistor Q2 is coupled to the current source I2. The current source I2 is coupled between the emitter of the transistor Q2 and the lower rail voltage or potential V−, which can be ground potential in some cases.

The bypass switch 30 includes bypass transistors Q3 and Q4. The bypass transistors Q3 and Q4 are depicted as bipolar junction transistors in FIG. 2. However, the bypass transistors Q3 and Q4 can be embodied as field effect transistors (FETs), and the concepts described herein are not limited to use with amplifiers or transistors of any particular type or technology. The bypass transistor Q3 is coupled in parallel with the transistor Q1. In that parallel arrangement, the collector of the bypass transistor Q3 is coupled to the collector of the transistor Q1 and the emitter of the bypass transistor Q3 is coupled to the emitter of the transistor Q1. The bypass transistor Q4 is also coupled in parallel with the transistor Q2. In that parallel arrangement, the collector of the bypass transistor Q4 is coupled to the collector of the transistor Q2 and the emitter of the bypass transistor Q4 is coupled to the emitter of the transistor Q2.

In one example, the bypass transistors Q3 and Q4 can be of the same size (e.g., same gate length and width) and the same type as the transistors Q1 and Q2. It is not necessary in every case, however, for the bypass transistors Q3 and Q4 to be matched to the transistors Q1 and Q2. The bypass transistors Q3 and Q4 can be smaller, larger, or of a different type than the transistors Q1 and Q2 in some cases. The bypass transistors Q3 and Q4 can also have the same or different threshold voltages than the transistors Q1 and Q2 depending on the design.

A differential input signal can be applied or provided to the amplifier 20 across the INp and INn inputs at the base terminals of the transistors Q1 and Q2. The input signal includes and applies a direct current (DC) bias component to the base terminals of the transistors Q1 and Q2, as would be understood in the field. The DC bias can set the transistors Q1 and Q2 in the linear mode of operation for amplification and results in current flow through the transistors Q1 and Q2 in connection with the current sources I1 and I2.

The bypass transistors Q3 and Q4 in the bypass switch 30 receive an “Sq” control signal from the control circuit 40. The “Sq” control signal is coupled to the base terminals of the bypass transistors Q3 and Q4, as shown in FIG. 2. The control circuit 40 includes switches S1 and S2, which are alternatively closed and opened during operation. The switches S1 and S2 are configured to pass voltages V1 or V2, respectively, to the base terminals of the bypass transistors Q3 and Q4 as the “Sq” control signal. The switches S1 and S2 are operated and configured such that only one of the switches S1 and S2 is closed at a time, with the other switch being open. Thus, the base terminals of the bypass transistors Q3 and Q4 are coupled to either V1 or V2 as the “Sq” control signal.

During normal amplification or non-squelch mode for the amplifier 20, the switch S2 is closed and the switch S1 is open. The bypass transistors Q3 and Q4 receive the voltage V2 as the “Sq” control signal in that case. V2 can be a relatively low voltage suitable to ensure that the bypass transistors Q3 and Q4 are turned off (e.g., cut or pinched off from current flow). Thus, during normal amplification or non-squelch mode for the amplifier 20, the bypass transistors Q3 and Q4 are turned off, and the bypass transistors Q3 and Q4 do not interfere with the amplification operation of the transistors Q1 and Q2.

During squelch mode for the amplifier 20, the switch S1 is closed and the switch S2 is open. The bypass transistors Q3 and Q4 receive the voltage V1 as the “Sq” control signal in that case. V1 can be a voltage larger than V2 and a voltage large enough to ensure that the bypass transistors Q3 and Q4 are turned on (e.g., a voltage that ensures currents I1 and I2 flow through or substantially through the bypass transistors Q3 and Q4). The voltage V1 can be set by design, as described in further detail below. As one example, the voltage V1 can be set or selected to be large enough to place the bypass transistors Q3 and Q4 into active region. As another example, the voltage V1 can be set or selected to be larger than the DC bias component of any input signal applied at the INp and INn inputs for the transistors Q1 and Q2, to ensure that current is bypassed from the transistors Q1 and Q2 to the bypass transistors Q3 and Q4.

During squelch mode for the amplifier 20, the bypass transistors Q3 and Q4 are biased and turned on. With the proper selection of V1 at an operating bias point for Q3 and Q4 that is greater than that applied to Q1 and Q2, a majority of the I1 and I2 current will flow through the bypass transistors Q3 and Q4 rather than through the amplifier transistors Q1 and Q2. The amplifier transistors Q1 and Q2 are starved or largely starved of current in this squelch mode. Under these conditions, the input signals at the INp and INn inputs will see high impedance nodes at the base terminals of the amplifier transistors Q1 and Q2. Even if the amplifier transistors Q1 and Q2 are not entirely starved from current flow, the amplification provided by the transistors Q1 and Q2 can be very low and relatively negligible during squelch mode operation. The gain of the transistors Q1 and Q2 can be reduced by an order of 100-fold or more during squelch mode operation.

It is not necessary in all cases for the transistors Q1 and Q2 to be turned completely off more during squelch mode. Additionally, the amount of power being consumed by the amplifier circuit 10 does not change (or does not change significantly) depending on the mode of operation. The amplifier circuit 10 consumes nearly the same amount of power during both non-squelch and squelch modes, and the currents through the current sources I1 and I2 can remain the same in both modes.

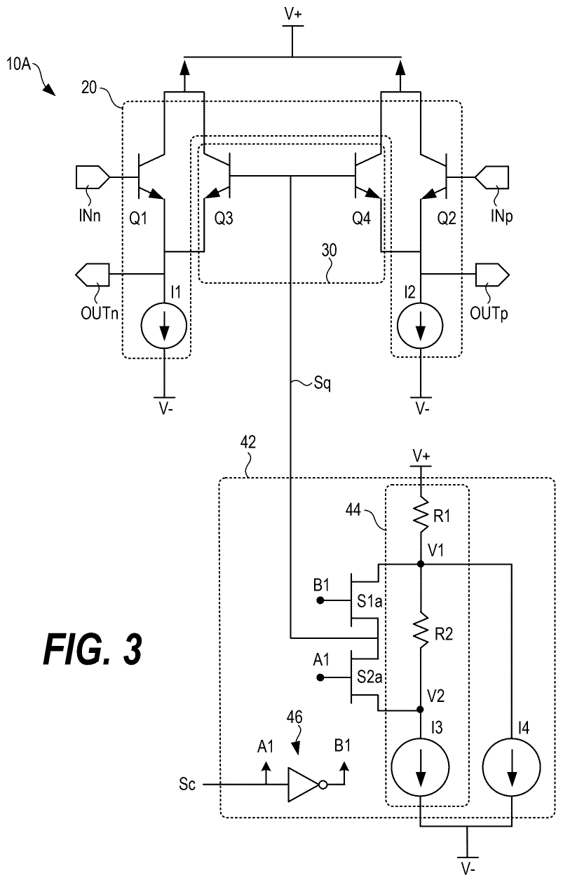

Before turning to FIG. 3, it is noted that the amplifier circuit 10 is not exhaustively illustrated in FIG. 2, and the amplifier circuit 10 can include additional components that are not shown. For example, one or more resistors or other circuit components can be coupled between the transistors Q1 and Q2 and the upper rail voltage V+, between the emitters of the transistors Q1 and Q2 and the lower rail voltage V−, and at other locations. Coupling, blocking, and other capacitors can also be relied upon as would be understood in the field.

The current sources I1 and I2 are representative in FIG. 2, and each can be implemented as any suitable type of current source or related biasing circuitry for the transistors Q1 and Q1. Examples of the current sources I1 and I2 include transistor-based current mirrors, current regulators, resistors, and combinations thereof, but the current sources I1 and I2 are not limited to any particular type of implementation. The current sources I1 and I2 can also be implemented or embodied as variable current sources in some cases.

The upper rail voltage V+ can be any suitable voltage, and the lower rail voltage V− can be any suitable voltage or potential (e.g., including ground potential in some cases) that is less than the upper rail voltage V+. The voltages V+ and V− can be selected, respectively, based on the target biasing voltage or voltage range for the amplifier circuit 10. The difference in potential between the voltages V+ and V− can be any suitable potential difference based on the target biasing voltage or voltage range for the amplifier circuit 10.

FIG. 3 illustrates another example amplifier circuit 10A with squelch circuit according to various examples described herein. The amplifier circuit 10A can be embodied in various ways, such as using discrete components, as an integrated circuit device formed on a substrate, or as a combination of discrete components and integrated devices. The amplifier circuit 10A is provided as a representative example of an amplifier stage with a squelch circuit and squelch functionality. The amplifier circuit 10A is not exhaustively illustrated in FIG. 3, and the amplifier circuit 10A can include additional components that are not shown. The amplifier circuit 10A can also omit certain components in some cases.

The amplifier circuit 10A includes the amplifier 20 and a squelch circuit coupled to the amplifier 20. The squelch circuit includes the bypass switch 30 and a control circuit 42. The amplifier 20 and the bypass switch 30 are similar to the amplifier 20 and the bypass switch 30 shown in FIG. 2. The amplifier circuit 10A also includes a more particular example of the control circuit 40 shown in FIG. 2.

The control circuit 42 includes a biased voltage divider leg 44, a current source I4, a pair of control switch transistors S1a and S2a, and switch control logic 46. The biased voltage divider leg 44 includes a series-connected pair of resistors R1 and R2, which are biased by a current source I3. More particularly, the resistor R1 is coupled between the upper rail voltage or potential V+, at one end, and the resistor R2 at another end. The resistor R2 is coupled between the resistor R1, at one end, and the current source I3 at another end. The current source I3 is coupled between R2 and the lower rail voltage or potential V−.

Voltages V1 and V2 are identified at two different nodes along the biased voltage divider leg 44 as shown in FIG. 3. The current source I4, which can be a variable current source, is coupled between the node between the resistors R1 and R2 and the lower rail voltage or potential V−. Overall, the voltages V1 and V2 are determined based on the upper and lower rail voltages V+ and V−, the respective impedance values of the resistors R1 and R2, and the design and operation of the current sources I3 and I4, as described below.

The current sources I3 and I4 are representative in FIG. 3, and each can be implemented as any suitable type of current source. Examples of the current sources I3 and I4 include transistor-based current mirrors, current regulators, and related circuits, but the current sources I3 and I4 are not limited to any particular type of implementation. The current sources I3 and I4 can also be implemented or embodied as variable current sources in some cases.

The “Sq” control signal is an output from the control circuit 42. The “Sq” control signal is taken from a node between the control switch transistors S1a and S2a, as shown in FIG. 2. The control switch transistors S1a and S2a are coupled in series across the resistor R2. The control switch transistors S1a and S2a can be embodied as FET transistors, such as N-channel FET transistors, but other types of transistors can be relied upon. The gate terminals of the control switch transistors S1a and S2a are coupled to the B1 and A1 control signals from the switch control logic 46, respectively, as shown in FIG. 3. Other control arrangements or couplings can be relied upon to achieve a similar effect depending on the design.

The switch control logic 46 can be implemented in a number of different ways, and the switch control logic 46 is implemented as a type of logic inverter in FIG. 2. A squelch control “Sc” signal can be generated by a controller (not shown) and provided as an input to the switch control logic 46. The switch control logic 46 provides complementary A1 and B1 control signals based on the “Sc” input signal. The A1 and B1 control signals are coupled to the gate terminals of the control switch transistors S2a and S1a, respectively.

The A1 and B1 control signals are always complimentary (i.e., opposite) to each other based on the design of the switch control logic 46. Thus, the control switch transistors S1a and S2a are operated complimentary to each other, with one of the control switch transistors S1a and S2a being open (i.e., with an open channel) and another one of the control switch transistors S1a and S2a being closed (i.e., with a closed channel). If the control switch transistor S1a is closed and the control switch transistor S2a is open, then the “Sq” control signal will be set at (i.e., coupled to) the V1 voltage by S1a. If the control switch transistor S1a is open and the control switch transistor S2a is closed, then the “Sq” control signal will be set at the V2 voltage by S2a. Similar to the example described above with reference to FIG. 2, the bypass transistors Q3 and Q4 in the bypass switch 30 can be operated based on the V1 or V2 voltages of the “Sq” control signal.

During normal amplification or non-squelch mode for the amplifier 20, the A1 control signal closes the transistor S2a, and the B1 control signal opens the transistor S1a. The “Sq” control signal will be set at the V2 voltage by S2a in that case. The bypass transistors Q3 and Q4 receive the voltage V2, which is tied closely to the lower rail voltage or potential V− by the current source I4, to ensure that the bypass transistors Q3 and Q4 are turned off (e.g., cut or pinched off from current flow). Thus, during normal amplification or non-squelch mode for the amplifier 20, the bypass transistors Q3 and Q4 are turned off, and the bypass transistors Q3 and Q4 do not interfere with the amplification operation of the transistors Q1 and Q2.

During squelch mode for the amplifier 20, the A1 control signal opens the transistor S2a, and the B1 control signal closes the transistor S1a. The “Sq” control signal will be set at the V1 voltage by S1a in that case, and the bypass transistors Q3 and Q4 receive the voltage V1. V1 can be a voltage larger than V2 and a voltage large enough to ensure that the bypass transistors Q3 and Q4 are turned on (e.g., with current flowing through the bypass transistors Q3 and Q4). As examples, the voltage V1 can be set or selected to be large enough to place the bypass transistors Q3 and Q4 into saturation. As another example, the voltage V1 can be set or selected to be larger than the DC bias component of any input signal applied at the INn and INp inputs for the transistors Q1 and Q2.

During squelch mode for the amplifier 20, the bypass transistors Q3 and Q4 are biased and turned on. With the proper selection of V1 at an operating bias point for Q3 and Q4 that is greater than that applied to Q1 and Q2, a majority of the I1 and I2 current will flow through the bypass transistors Q3 and Q4 rather than through the amplifier transistors Q1 and Q2. The amplifier transistors Q1 and Q2 are starved or largely starved of current in this squelch mode. Under these conditions, the input signals at the INp and INn inputs will see a high impedance node. Even if the amplifier transistors Q1 and Q2 are not entirely cut or pinched off from current flow, the amplification provided by the transistors Q1 and Q2 can be very low and relatively negligible during squelch mode or operation. The gain of the transistors Q1 and Q2 can be reduced by an order of 100-fold or more during squelch mode.

V1 is always a higher potential than V2 in the biased voltage divider leg 44 of the control circuit 42, as would be understood in the field. The individual resistances of R1 and R2 and the currents of I3 and I4 can be designed and tailored to set the potentials of V1 and V2 based on the design considerations described herein. One objective of the control circuit 42 is to provide low power control operation. As one example to achieve low power operation, I3 can be designed for a relatively small current value and R2 can be selected as a relatively large value. I4 can also be designed for a relatively small current. I4 can also be implemented as a variable current source, with control. For example, the current sourced by I4 can be controlled by the “Sc” signal, the A1 signal, or the B1 signal. For example, I4 can be turned off during normal amplification or non-squelch mode. I4 can be turned on during squelch mode only in some cases, and the current drawn by I4 can be selected along with the resistance of RI to define the voltage of V1 for squelch mode.

The transistors described herein, including the transistors Q1, Q2, Q3, Q4, S1a, and S2a can be implemented as a range of different types of transistors formed in a range of different semiconductor materials. The transistors can be formed as bipolar junction transistors or FETs, and the concepts can be applied to a range of transistor types. Among other types of FET transistors, the transistors described herein can be formed as high-electron mobility transistors (HEMTs), pseudomorphic high-electron mobility transistors (pHEMTs), metamorphic high-electron mobility transistors (mHEMTs), and other types of transistors. The FETs can include metal oxide or insulator semiconductor (MOSFET or MISFET) transistors and metal-semiconductor field-effect transistor (MESFETs). The transistors can include one or more field plates, such as source-connected field plates, gate-connected field plates, or both source-connected and gate-connected field plates. The transistors can be implemented in gallium arsenide (GaAs), gallium nitride (GaN), GaN materials, and other semiconductor materials on or over a range of different substrates. As non-limiting examples, the transistors can be structured as enhancement or depletion mode FET transistors, such as a depletion mode GaAs pHEMT transistors, as GaN HEMT transistors, as GaN materials HEMT transistors, or as related power transistors.

The transistors and other active devices described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGalIn)-based Nitrides), GaAs, InP, InGaP, AlGaAs, etc. devices. However, the concepts may be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)}), among others. Typically, when present, arsenic and/or phosphorous are at low concentrations (e.g., less than 5 weight percent). The gallium nitride materials can be n-type doped, p-type doped, or unintentionally doped (UID).

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0). The GaN can be n-type doped, p-type doped, or unintentionally doped (UID).

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially available semiconductor processing tools available at the time, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. An amplifier circuit with squelch function comprising:
an amplifier; and
a squelch circuit coupled to the amplifier and configured to squelch an output of the amplifier by bypassing current from the amplifier.

2. The amplifier circuit according to claim 1, wherein the squelch circuit comprises:
a bypass switch coupled with a transistor of the amplifier; and
a control circuit coupled to the bypass switch and configured to control operation of the bypass switch.

3. The amplifier circuit according to claim 2, wherein the bypass switch is configured to bypass current from the amplifier through the bypass switch based on a control signal from the control circuit.

4. The amplifier circuit according to claim 2, wherein the bypass switch comprises a bypass transistor coupled in parallel with a transistor of the amplifier.

5. The amplifier circuit according to claim 1, wherein:
the amplifier comprises a pair of common collector transistors; and
the squelch circuit comprises:
a first bypass switch coupled in parallel with a first transistor among the pair of common collector transistors;
a second bypass switch coupled in parallel with a second transistor among the pair of common collector transistors; and
a control circuit coupled and configured to control operation of the first and second bypass switches.

6. The amplifier circuit according to claim 5, wherein, to squelch the amplifier, the control circuit is configured to provide, to the first and second bypass switches, a control signal having a potential greater than a common DC bias at inputs of the pair of common collector transistors.

7. The amplifier circuit according to claim 5, wherein the control circuit comprises:
a biased voltage divider leg comprising a pair of resistors biased by a current source;
a variable current source coupled at a node between the pair of resistors; and
a pair of control switch transistors coupled across a resistor among the pair of resistors in the biased voltage divider leg.

8. The amplifier circuit according to claim 7, wherein a squelch control signal is coupled from between the pair of control switch transistors to base terminals of the first bypass switch and the second bypass switch.

9. The amplifier circuit according to claim 1, wherein the amplifier comprises a stage in a multi-stage amplifier.

10. An amplifier circuit with squelch function comprising:
an amplifier;
a bypass switch coupled with a transistor of the amplifier; and
a control circuit coupled to the bypass switch and configured to control operation of the bypass switch for squelch functionality.

11. The amplifier circuit according to claim 10, wherein the bypass switch is configured to bypass current from the amplifier through the bypass switch based on a control signal from the control circuit.

12. The amplifier circuit according to claim 10, wherein the bypass switch comprises a bypass transistor coupled in parallel with a transistor of the amplifier.

13. The amplifier circuit according to claim 10, wherein:
the amplifier comprises a pair of common collector transistors;
the bypass switch comprises:
a first bypass switch coupled in parallel with a first transistor among the pair of common collector transistors; and
a second bypass switch coupled in parallel with a second transistor among the pair of common collector transistors; and
the control circuit is configured to control operation of the first and second bypass switches.

14. The amplifier circuit according to claim 13, wherein, to squelch the amplifier, the control circuit is configured to provide, to the first and second bypass switches, a control signal having a potential greater than a common DC bias at inputs of the pair of common collector transistors.

15. The amplifier circuit according to claim 14, wherein the control circuit comprises:
a biased voltage divider leg comprising a pair of resistors biased by a current source;
a variable current source coupled at a node between the pair of resistors; and
a pair of control switch transistors coupled across a resistor among the pair of resistors in the biased voltage divider leg.

16. The amplifier circuit according to claim 15, wherein a squelch control signal is coupled from between the pair of control switch transistors to base terminals of the first bypass switch and the second bypass switch.

17. An amplifier circuit with squelch function comprising:
an amplifier;
a bypass switch coupled to the amplifier; and
a control circuit coupled to the bypass switch and configured to control operation of the bypass switch for squelch functionality, wherein the bypass switch is configured to bypass current from the amplifier based on a control signal from the control circuit.

18. The amplifier circuit according to claim 17, wherein:
the amplifier comprises a pair of common collector transistors;
the bypass switch comprises:
a first bypass switch coupled in parallel with a first transistor among the pair of common collector transistors; and
a second bypass switch coupled in parallel with a second transistor among the pair of common collector transistors; and
the control circuit is configured to control operation of the first and second bypass switches.

19. The amplifier circuit according to claim 18, wherein, to squelch the amplifier, the control circuit is configured to provide, to the first and second bypass switches, a control signal having a potential greater than a common DC bias at inputs of the pair of common collector transistors.

20. The amplifier circuit according to claim 18, wherein the control circuit comprises:
a biased voltage divider leg comprising a pair of resistors biased by a current source;
a variable current source coupled at a node between the pair of resistors; and
a pair of control switch transistors coupled across a resistor among the pair of resistors in the biased voltage divider leg.
